(19) United States
(12) Patent Application Publication
(10) Pub. No.: US 2024/0049505 A1
(43) Pub. Date: Feb. 8, 2024

(54) DISPLAY TERMINAL

(71) Applicant: HUAWEI TECHNOLOGIES CO., LTD., Shenzhen (CN)

(72) Inventors: Yingming LI, Shanghai (CN); Senjun CHEN, Shanghai (CN); Chien Feng YEH, Shenzhen (CN); Renxuan QIN, Shanghai (CN); Chao XU, Shanghai (CN); Haisheng TU, Shanghai (CN)

(73) Assignee: HUAWEI TECHNOLOGIES CO., LTD., Shenzhen, GD (CN)

(21) Appl. No.: 17/642,001

(22) PCT Filed: Jul. 23, 2020
(86) PCT No.: PCT/CN2020/103865

§ 371 Date: Mar. 10, 2022

(30) Foreign Application Priority Data
Sep. 12, 2019 (CN) 201910866768.X

(51) Int. Cl. H10K 59/12; H10K 59/82; H10K 59/80; H10K 59/00; G02F 1/1333; G02F 1/1337; G02F 1/133

(52) U.S. Cl. CPC H10K 59/1201; H10K 59/82; H10K 59/871; H10K 59/751; G02F 1/133317; G02F 1/133325; G02F 1/133769; G02F 1/13306

(57) ABSTRACT

Embodiments of this application provide a display terminal, and relate to the field of display technologies, to solve the problem that the overall screen-to-body ratio decreases due to a receiver disposed on a display terminal. The display terminal includes a middle frame, a display module, a vibrator, and at least one vibrating plate. The display module is connected to the middle frame, and an accommodation space is formed between the display module and the middle frame. At least a part of the vibrator is disposed in the accommodation space. The vibrator is connected to the display module or the middle frame. The vibrating plate is located in the accommodation space. An upper surface of the vibrating plate is connected to a lower surface of the display module. A lower surface of the vibrating plate faces the middle frame.

This application claims priority to Chinese Patent Application No. 201910866768.X, filed with the China National Intellectual Property Administration on Sep. 12, 2019, and entitled “DISPLAY TERMINAL,” which is incorporated herein by reference in its entirety.

### TECHNICAL FIELD

This application relates to the field of display technologies, and in particular, to a display terminal.

### BACKGROUND

Users place an increasingly higher requirement on the overall screen-to-body ratio of a display terminal. Currently, the top of the front of a display terminal, for example, needs to be punctured to mount a receiver. In this way, a display cannot completely occupy the front of the display terminal due to the presence of the receiver. Consequently, the overall screen-to-body ratio decreases, and this is not conducive to the no-hole design or full-screen design of a display terminal.

### SUMMARY

Embodiments of this application provide a display terminal, to solve the problem that the overall screen-to-body ratio decreases due to a receiver disposed on a display terminal.

To achieve the foregoing objective, this application uses the following technical solutions.

According to an aspect of the embodiments of this application, a display terminal is provided. The display terminal includes a middle frame, a display module, a vibrator, and at least one vibrating plate. The display module is connected to the middle frame, and an accommodation space is formed between the display module and the middle frame. At least a part of the vibrator is disposed in the accommodation space. The vibrator is connected to the display module or the middle frame. The vibrating plate is located in the accommodation space. The upper surface of the vibrating plate is connected to the lower surface of the display module. The lower surface of the vibrating plate faces the middle frame. In a direction perpendicular to the upper surface of the vibrating plate, the vibrator and the vibrating plate are configured to drive the display module to vibrate up and down. In this way, the vibrating plate and the vibrator may have a same vibration phase, and therefore the vibration of the vibrating plate and the vibrator can be superimposed and then coupled to the display module, to increase, in a vibration process, the amplitude of the display module that serves as a diaphragm and increase the volume of a high-frequency sound emitted by the display terminal.

Optionally, the display terminal further includes a first support sheet. The first support sheet is located between the vibrating plate and the display module. The upper surface of the first support sheet is connected to the lower surface of the display module, and the lower surface of the first support sheet is connected to the upper surface of the vibrating plate. The area of the upper surface of the first support sheet is greater than the area of the upper surface of the vibrating plate. In this way, there is a relatively large contact area between the first support sheet and the display module because the first support sheet is of a sheet-like structure. Therefore, by setting the upper surface and the lower surface of the first support sheet to be respectively in contact with the display module and the vibrating plate, the effective contact area between the vibrating plate and the display module may be increased, so that the driving force provided by the vibrating plate and the vibrator for the display module in a vibration process can be more evenly applied to the display module, to reduce the probability that the display module is damaged in the vibration process. In addition, by using the first support sheet, the area of a deformation region of the display module may be further increased, so that the driving force provided by the vibrating plate and the vibrator for the display module in the vibration process can be transferred to the display module to a greater extent, to improve the efficiency of driving, by the vibrating plate and the vibrator, the display module to vibrate, reduce power consumption, and improve the effect for implementing sound on display.

Optionally, the vibrating plate is located between the vibrator and the display module, the lower surface of the vibrating plate is connected to the upper surface of the vibrator, and the lower surface of the vibrator is connected to the middle frame. In this way, in a process of vibrating up and down by the vibrator, driving force may be directly transferred to the vibrating plate, and is applied to the display module after being superimposed with the vibration of the vibrating plate.

Optionally, the area of the upper surface of the vibrating plate is greater than the area of the upper surface of the vibrator. In this way, there is a relatively large contact area between the upper surface of the vibrating plate and the display module because the vibrating plate is of a plate-like structure. Therefore, by setting the upper surface and the lower surface of the vibrating plate to be respectively in contact with the display module and the vibrator, the effective contact area between the vibrator and the display module may be increased, so that driving force provided by the vibrator for the display module in a vibration process can be more evenly applied to the display module, to reduce the probability that the display module is damaged in the vibration process. In addition, by increasing the area of the upper surface of the vibrating plate, the area of the deformation region of the display module may be further increased, so that the driving force provided by the vibrator for the display module in the vibration process can be transferred to the display module to a greater extent, to improve the efficiency of driving, by the vibrator, the display module to vibrate, reduce power consumption, and improve the effect for implementing sound on display.

Optionally, the display terminal further includes at least one first mass block. The first mass block is disposed on the lower surface of the vibrating plate. The region in which the vibrator is vertically projected on the lower surface of the vibrating plate and the region in which the first mass block is vertically projected on the lower surface of the vibrating plate do not overlap. In a deformation process of the vibrating plate, the first mass block may generate a vibration acceleration, and the acceleration is coupled to the display module by using the vibrating plate, so that the driving force coupled to the display module by using the vibrating plate can be increased, to increase the volume for implementing sound on display.

Optionally, the upper surface of the vibrator is connected to the lower surface of the display module, the lower surface of the vibrator is connected to the middle frame, and the region in which the vibrator is vertically projected on the lower surface of the display module and the region in which the vibrating plate is vertically projected on the lower surface of the display module do not overlap. In this way, by disposing the vibrating plate around the vibrator, the gap between the display module and the middle frame may be reduced, to reduce the thickness of the display terminal.

Optionally, the display terminal further includes a second support sheet. The second support sheet is located between the vibrator and the display module, the upper surface of the second support sheet is connected to the lower surface of the display module, and the lower surface of the second support sheet is connected to the upper surface of the vibrator. The area of the upper surface of the second support sheet is greater than the area of the upper surface of the vibrator. In this way, there is a relatively large contact area between the second support sheet and the display module because the second support sheet is of a sheet-like structure. Therefore, by setting the upper surface and the lower surface of the second support sheet to be respectively in contact with the display module and the vibrator, the effective contact area between the vibrator and the display module may be increased, so that the driving force provided by the vibrator for the display module in a vibration process can be more evenly applied to the display module, to reduce the probability that the display module is damaged in the vibration process. In addition, by using the second support sheet, the area of the deformation region of the display module may be further increased, so that the driving force provided by the vibrator for the display module in the vibration process can be transferred to the display module to a greater extent, to improve the efficiency of driving, by the vibrator, the display module to vibrate, reduce power consumption, and improve the effect for implementing sound on display.

Optionally, the display terminal further includes at least one second mass block. The second mass block is disposed on the lower surface of the second support sheet. The region in which the vibrator is vertically projected on the lower surface of the second support sheet and the region in which the second mass block is vertically projected on the lower surface of the second support sheet do not overlap. The manner of disposing the second mass block and technical effects are the same as the manner of disposing the first mass block. Details are not described herein.

Optionally, the display terminal further includes at least one third mass block. The third mass block is located on the lower surface of the vibrating plate. The manner of disposing the third mass block and technical effects are the same as the manner of disposing the first mass block. Details are not described herein.

Optionally, the display terminal further includes a first glue layer located on the upper surface of the vibrating plate. The first glue layer is disposed along the edge of the upper surface of the vibrating plate. Therefore, the shape and arrangement of the first glue layer can be set based on a deformation form and a deformation degree of the vibrating plate, so that the manner of disposing the first glue layer is more conducive to driving the display module to vibrate.

Optionally, the thickness of the vibrating plate ranges from 0.2 mm to 2 mm. When the thickness of the vibrating plate ranges from 0.2 mm to 2 mm, it may be ensured that the vibrating plate has a specific driving capability when the vibrating plate is prone to vibrate, and the impact of the thickness of the vibrating plate on the overall thickness of the display terminal may be alleviated.

Optionally, an adhesive layer is disposed between the display module and the middle frame. The thickness of the adhesive layer ranges from 0.2 mm to 0.5 mm. In this way, the adhesive layer can firmly bond the display module and the middle frame. In addition, in the thickness range, a larger thickness of the adhesive layer indicates a softer texture of the adhesive layer and a higher probability that the display module vibrates after force is applied. This is conducive to increasing the volume for implementing sound on display. In addition, a Young's modulus of the adhesive layer may range from 10 Mpa to 80 Mpa. In this case, a smaller Young's modulus of the adhesive layer indicates a softer boundary condition of the display terminal and a higher probability that the display module vibrates. In this way, the volume for implementing sound on display can be effectively increased.

Optionally, the vibrator includes a first magnetic object and a second magnetic object. The first magnetic object is connected to the display module, and the second magnetic object is connected to the middle frame. The first magnetic object is connected to a surface of the display module that faces the middle frame, and the second magnetic object may pass through a mounting hole, and be fastened to a second surface of the middle frame by using a bracket. In this case, a part of the second magnetic object may be located in the mounting hole, and therefore the space occupied by the vibrator in the accommodation space may be reduced, to reduce the gap between the display module and the middle frame, so as to reduce the thickness of the display terminal.

Optionally, the display terminal includes an audio digital processor, a first power amplifier, and a filter. The output end of the audio digital processor is coupled to the input end of the first power amplifier. The audio digital processor is configured to output an audio signal to the first power amplifier. A first output end of the first power amplifier is coupled to the filter, and a second output end of the first power amplifier is coupled to the vibrator. The first power amplifier is configured to amplify the audio signal, so that a vibration phase of the vibrator is a first phase. The output end of the filter is connected to the vibrating plate, and the filter is configured to filter the audio signal, so that the vibration phase of the vibrating plate is the first phase. When a CPU outputs a low-frequency signal, after the low-frequency signal passes through the audio digital processor and the first power amplifier, an audio signal that is at hundreds of kHz and output by the first power amplifier is applied to the vibrator, to drive the vibrator to vibrate. The vibrator that serves as an inductor filters out a part of the audio signal at hundreds of kHz, and vibrates under the action of the remaining low-frequency signal. In addition, after the audio signal that is at hundreds of kHz and output by the first power amplifier passes through the filter, a part of the audio signal at hundreds of kHz is filtered out, and the remaining low-frequency signal is applied to the vibrating plate. The vibrator and the vibrating plate are connected in parallel, and therefore the same voltage is applied to the vibrator and the vibrating plate. On this basis, under the driving of the low-frequency signal, there is relatively small impedance for the coil in the vibrator, and therefore a relatively strong current flows through the coil. There is relatively large impedance for the vibrating plate that serves as a capacitor, and therefore a relatively weak current flows through the vibrating plate. In this case, when the vibrator and the vibrating plate simultaneously vibrate, the vibration of the vibrator and the vibrating plate may be superimposed because the vibration phases are the same, and the vibrator serves as the main driving source to drive the display module to vibrate, to emit a low-frequency signal. Alternatively, when a CPU outputs a high-frequency signal, there is relatively large impedance for the coil in the vibrator, and therefore a relatively weak current flows through the coil. There is relatively small impedance for the vibrating plate that serves as a capacitor, and therefore a relatively strong current flows through the vibrating plate. In this case, when the vibrator and the vibrating plate simultaneously vibrate, the vibration of the vibrator and the vibrating may be superimposed, and the vibrating plate may serve as the main driving source to drive the display module to vibrate, to emit a high-frequency signal, so as to solve the problem that a high-frequency signal is emitted on the display at relatively low volume.

Optionally, the display terminal includes an audio digital processor, a first power amplifier, and a second power amplifier. The output frequency of the first power amplifier is greater than the output frequency of the second power amplifier. The output end of the audio digital processor is coupled to the input end of the first power amplifier and the second power amplifier. The audio digital processor is configured to output an audio signal to the first power amplifier and the second power amplifier. The output end of the first power amplifier is coupled to the vibrator. The first power amplifier is configured to amplify the audio signal, so that a vibration phase of the vibrator is a first phase. The output end of the second power amplifier is coupled to the vibrating plate, and the second power amplifier is configured to amplify the audio signal, so that a vibration phase of the vibrating plate is the first phase. The vibrator vibrates under driving of the first power amplifier, and when driving the display to emit a low-frequency signal, serves as the main driving source to drive the display module to vibrate. The vibrating plate vibrates under driving of the second power amplifier, and when driving the display to emit a high-frequency signal, serves as the main driving source to drive the display module to vibrate.

### BRIEF DESCRIPTION OF DRAWINGS

FIG. 1 is a schematic diagram of a structure of a display terminal according to an embodiment of this application;

FIG. 2 is a schematic diagram of a structure of a display module shown in FIG. 1;

FIG. 3 is another schematic diagram of a structure of a display module shown in FIG. 1;

FIG. 4a is a schematic diagram of a structure of connection between a display module and a middle frame according to an embodiment of this application;

FIG. 4b is a schematic diagram of a structure of connection between a display module, a middle frame, and a housing according to an embodiment of this application;

FIG. 5a is a schematic diagram of a structure of another display terminal according to an embodiment of this application;

FIG. 5b is a schematic diagram of a specific structure of a vibrator in FIG. 5a;

FIG. 6a is a schematic diagram of a structure of another display terminal according to an embodiment of this application;

FIG. 6b is a schematic diagram of a structure of a first glue layer in FIG. 6a;

FIG. 6c is a schematic diagram of another structure of a first glue layer in FIG. 6a;

FIG. 6d is a schematic diagram of another structure of a first glue layer in FIG. 6a;

FIG. 6e is a schematic diagram of another structure of a first glue layer in FIG. 6a;

FIG. 7a is a schematic diagram of a structure of another display terminal according to an embodiment of this application;

FIG. 7b is a schematic diagram of a manner of disposing a first mass block in FIG. 7a;

FIG. 7c is a schematic diagram of another manner of disposing a first mass block in FIG. 7a;

FIG. 7d is a schematic diagram of another manner of disposing a first mass block in FIG. 7a;

FIG. 8a is a schematic diagram of a structure of another display terminal according to an embodiment of this application;

FIG. 8b is a schematic diagram of a structure of another display terminal according to an embodiment of this application;

FIG. 9a is a schematic diagram of a structure of another display terminal according to an embodiment of this application;

FIG. 9b is a schematic diagram of a structure of a vibrating plate in FIG. 9a;

FIG. 9c is a schematic diagram of another structure of a vibrating plate in FIG. 9a;

FIG. 9d is a schematic diagram of a structure of another display terminal according to an embodiment of this application;

FIG. 9e is a schematic diagram of a structure of another display terminal according to an embodiment of this application;

FIG. 9f is a schematic diagram of a manner of disposing a third mass block in FIG. 9e;

FIG. 10 is a schematic diagram of a structure of a circuit configured to drive a vibrator and a vibrating plate to vibrate according to an embodiment of this application;

FIG. 11a is a schematic diagram of a structure of another circuit configured to drive a vibrator and a vibrating plate to vibrate according to an embodiment of this application;

FIG. 11b is a schematic diagram of a structure of another circuit configured to drive a vibrator and a vibrating plate to vibrate according to an embodiment of this application;

FIG. 11c is a schematic diagram of a structure of another circuit configured to drive a vibrator and a vibrating plate to vibrate according to an embodiment of this application; and

FIG. 11d is a schematic diagram of a structure of another circuit configured to drive a vibrator and a vibrating plate to vibrate according to an embodiment of this application.

### REFERENCE NUMERALS

01: Display terminal; 10: Display module; 11: Middle frame; 112: Bearing part; 113: Frame; 300: Audio digital processor; 12: Housing; 101: Display; 102: BLU; 103: Cover; 110: Bearing platform; 111: Adhesive layer; 20: Accommodation space; 31: Vibrator; 32: Vibrating plate; 122: Mounting hole; 123: Bracket; 311: First magnetic object; 312: Second magnetic object; 321a: First glue layer; 321b: Second glue layer; 321c: Third glue layer; 321d: Fourth glue layer; 321e: Fifth glue layer; 322: First mass block; 323: First support sheet; 324: Second support sheet; 325: Second mass block; 326: Third mass block; 41: Audio signal receiving module; 41: Sound effect operation module; 301: First power amplifier; 302: Filter; 303: Second power amplifier; 304: Third power amplifier; and 33: Moving coil speaker.

### DESCRIPTION OF EMBODIMENTS

The following describes the technical solutions in the embodiments of this application with reference to the accompanying drawings in the embodiments of this application. It is clearly that the described embodiments are merely a part rather than all of the embodiments of this application.

The following terms “first” and “second” are merely intended for a purpose of description, and shall not be understood as an indication or implication of relative importance or implicit indication of a quantity of indicated technical features. Therefore, a feature limited by “first” or “second” may explicitly or implicitly include one or more features. In the descriptions of this application, unless otherwise stated, “a plurality of” means two or more than two.

In addition, in this application, orientation terms such as “upper”, “lower”, “left”, and “right” may be defined by, but are not limited to, orientations of components schematically placed in the accompanying drawings. It should be understood that these orientation terms may be relative concepts, and are used for description and clarification of “relative”, and may change correspondingly according to a change in a placement orientation of a component drawing in the drawings.

In this application, unless otherwise expressly specified and limited, the term “connection” should be understood in a broad sense. For example, “connection” may be a fixed connection, a detachable connection or an integral connection; and may be a direct connection or an indirect connection by using an intermediate medium. In addition, the term “coupled” may be a manner of implementing an electrical connection for signal transmission.

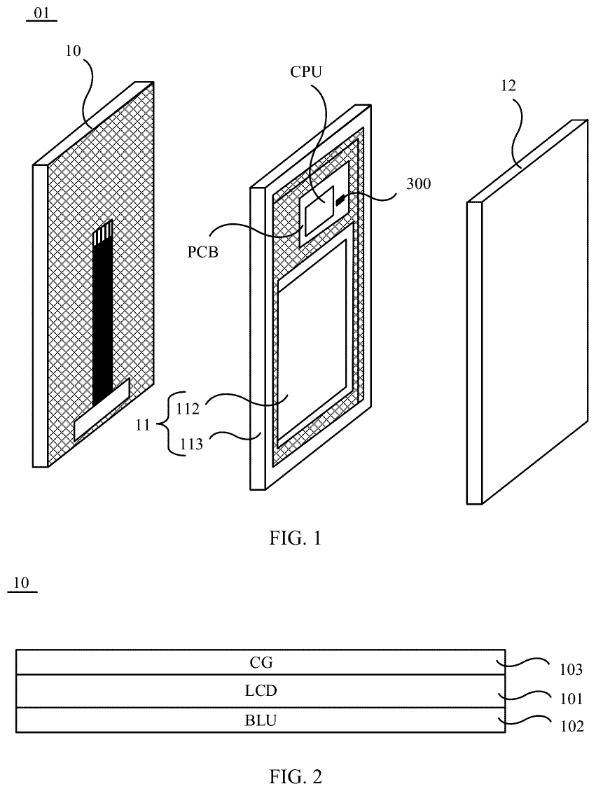

The embodiments of this application provide a display terminal. The display terminal includes, for example, a mobile phone, a tablet computer, a personal digital assistant (PDA), or a vehicle-mounted computer. A specific form of the display terminal is not specially limited in the embodiments of this application. For ease of description, the following provides description by using an example in which the display terminal is a mobile phone shown in FIG. 1.

As shown in FIG. 1, the display terminal 01 mainly includes but is not limited to a display module 10. As shown in FIG. 2, the display module 10 includes a display panel (DP) 101.

In some embodiments of this application, the display panel 101 may be a liquid crystal display (LCD). In this case, the display module 10 further includes a back light unit (BLU) 102 configured to provide a light source for the LCD.

Alternatively, in some other embodiments of this application, as shown in FIG. 3, the display panel 101 is an organic light emitting diode (OLED) display, and the OLED display can implement self-luminescence. Therefore, no BLU is disposed in the display module 10.

It should be noted that a substrate in the OLED display may be made of a flexible resin material. In this case, the OLED display is a flexible display, and therefore the mobile phone that includes the OLED display may be a foldable mobile phone.

Alternatively, the substrate in the OLED display may be made of a hard-textured material, such as glass. In this case, the OLED display is a hard display.

In some embodiments of this application, as shown in FIG. 2 or FIG. 3, the display module 10 further includes a cover 103 located on a display side of the display panel 101, for example, a cover glass (CG). The cover glass has specific toughness.

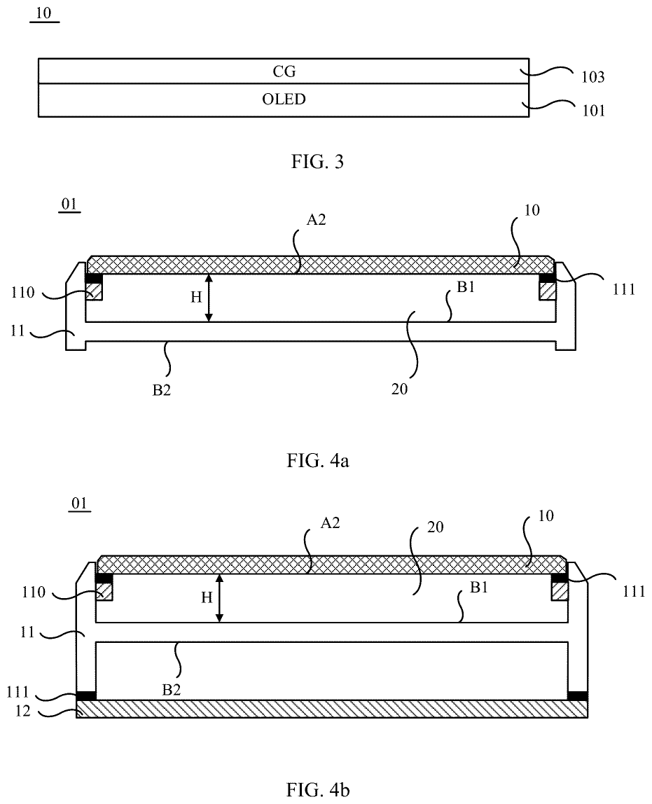

In addition, the display terminal 01 further includes a middle frame 11 shown in FIG. 1. The display module 10 is mounted on the middle frame 11. In some embodiments of this application, as shown in FIG. 4a, a bearing platform 110 is disposed on a side that is of the middle frame 11 and close to the display module 10. An adhesive layer 111 is attached to the bearing platform 110. The display module 10 is fastened to the middle frame 11 by using the adhesive layer 111, so that the display module 10 is connected to the middle frame 11, to mount the display module 10 on the middle frame 11.

For example, the adhesive layer 111 may be foam adhesive. The foam adhesive has specific elasticity and can be deformed under action of external force.

In addition, the display terminal 01 further includes the middle frame 11 shown in FIG. 1. Internal elements such as a battery, a printed circuit board (PCB), a camera, and an antenna are mounted on a surface (a second surface B2 in FIG. 4a) that is of the middle frame 11 and away from the display module 10. As shown in FIG. 1, a central processing unit (CPU) may be disposed on the PCB.

In this case, the display terminal 01 may further include a housing 12 shown in FIG. 1. As shown in FIG. 4b, the housing 12 is disposed on a side on which the second surface B2 of the middle frame 11 is located, and may be connected to the middle frame 11 by using the adhesive layer 111. The housing 12 can protect the internal elements mounted on the middle frame 11.

In addition, as shown in FIG. 4a, there is a gap H between the lower surface A2 (namely, a surface that is of the display module 10 and that faces the middle frame 11) of the display module 10 fastened to the bearing platform 110 and a first surface B1 of the middle frame 11. Accommodation space 20 is formed between the display module 10 and the middle frame 11 based on the gap H.

It should be noted that as shown in FIG. 1, the middle frame 11 includes a bearing part 112 configured to carry the battery and the PCB and a frame 113 disposed around the bearing part 112. The bearing part 112 is parallel or approximately parallel to the display module 10. In this case, in the embodiments of this application, facing the middle frame 11 may mean facing the bearing part 112 of the middle frame 11.

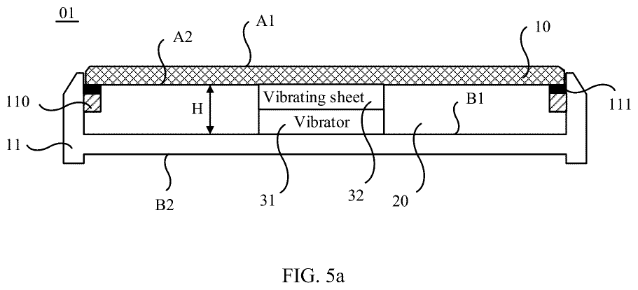

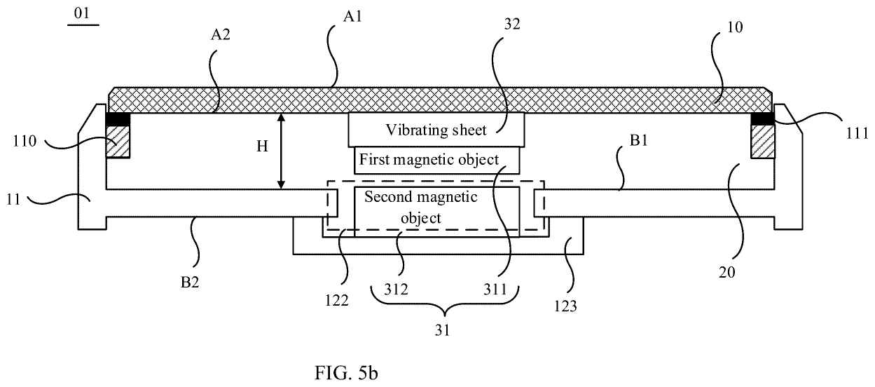

On this basis, the display terminal 01 further includes a vibrator 31 shown in FIG. 5a. At least a part of the vibrator 31 is disposed in the accommodation space 20. The vibrator 31 is connected to the display module 10 or the middle frame 11. The vibrator 31 is configured to drive, in a direction perpendicular to the upper surface A1 (namely, a display surface of the display module 10) (shown in FIG. 5a) of the display module 10 based on a driving signal output by an audio digital processor (DSP) 300 shown in FIG. 1, the display module 10 to vibrate. In this way, driven by the vibrator 31, the display module 10 that serves as a diaphragm drives, in a vibration process, air to generate a sound, to implement sound on display.

It should be noted that, at least a part of the vibrator 31 being disposed in the accommodation space 20 means that in some embodiments of this application, the entire vibrator 31 may be disposed in the accommodation space 20. For example, the vibrator 31 may be a linear vibrator.

Alternatively, at least a part of the vibrator 31 being disposed in the accommodation space 20 means that as shown in FIG. 5b, a mounting hole 122 may be disposed on the middle frame 11, and a part of the vibrator 31 passes through the mounting hole 122, and is connected to the second surface B2 of the middle frame 11.

For example, the vibrator 31 may include a first magnetic object 311 and a second magnetic object 312 that move relatively in a working state. The first magnetic object 311 is connected to the surface that is of the display module 10 and that faces the middle frame 11, and the second magnetic object 312 may pass through the mounting hole 122, and be fastened to the second surface B2 of the middle frame by using a bracket 123.

In this case, a part of the second magnetic object 312 may be located in the mounting hole 122, and therefore space occupied by the vibrator 31 in the accommodation space 20 may be reduced, to reduce the gap H between the display module 10 and the middle frame 11, so as to reduce the thickness of the display terminal 01.

The first magnetic object 311 may be a coil, and the second magnetic object 312 may be a magnet. Alternatively, the first magnetic object 311 is a magnet, and the second magnetic object 312 is a coil. In this case, after receiving the driving signal output by the audio digital processor 300, the coil generates an alternating magnetic field. Intensity of the magnetic field is directly proportional to the intensity of the current in the coil. The magnet can generate a constant magnetic field of constant intensity and in a constant direction. With interaction of the two magnetic fields, the coil may cut a magnetic induction line in the direction perpendicular to the lower surface A1 (shown in FIG. 5a) of the display module 10, and vibrate up and down, to drive the display module 10 to vibrate.

A higher frequency of a sound signal for implementing sound on display indicates larger inductance of the coil. In this case, even if the audio digital processor 300 outputs a maximum voltage, the current in the coil is reduced due to an increase in impedance of the coil. It may be learned from the foregoing description that the intensity of the magnetic field generated by the coil is directly proportional to the intensity of the current in the coil, and therefore the intensity of the magnetic field generated by the coil is also reduced. Therefore, in a process of implementing sound on display, there is small power for a high-frequency sound, and consequently the display terminal 01 emits the high-frequency sound at low volume.

To increase the volume of the high-frequency sound, the display terminal 01 further includes at least one vibrating plate 32 shown in FIG. 5a. The vibrating plate 32 is located in the accommodation space 20. An upper surface (namely, a surface that is of the vibrating plate 32 and that faces the display module 10) of the vibrating plate 32 is connected to the lower surface A2 of the display module 10, and the lower surface (which is disposed opposite to the upper surface of the vibrating plate 32) of the vibrating plate 32 faces the middle frame 11.

The vibrating plate 32 is configured to: after receiving the driving signal output by the audio digital processor 300, drive, in a direction perpendicular to the upper surface of the vibrating plate 32 (or the upper surface A1 of the display module 10), the display module 10 to vibrate up and down. In this way, the vibrating plate 32 and the vibrator 31 may have a same vibration phase, and therefore the vibration of the vibrating plate 32 and the vibrator 31 can be superimposed and then coupled to the display module 10, to increase, in a vibration process, the amplitude of the display module 10 that serves as a diaphragm and increase the volume of the high-frequency sound emitted by the display terminal 01.

On this basis, the vibrating plate 32, the display module 10, and the first magnetic object 311 in the vibrator 31 may form a sound emitting system of the display terminal 01. In the sound emitting system, the display module 10 serves as the diaphragm, vibrates under joint driving of the vibrator 31 and the vibrating plate 32, and drives, in the vibration process, air to emit a sound, to implement sound on display. In this case, the sound system can implement a function of a receiver or a speaker, to play an audio signal.

It can be learned from the foregoing description that the display panel 101 in the display module 10 may be an LCD or an OLED display. In addition, compared with the LCD, the OLED display can self-illuminate. Therefore, no BLU is disposed in the display module 10, and the display module 10 is thin. When the display module 10 serves as the diaphragm to implement the sound on display, deformation is more likely to occur, so that a sound effect of the diaphragm is better.

Structures and disposing manners of the vibrator 31 and the vibrating plate 32 are described below by using examples.

### Example 1

In this example, as shown in FIG. 5a, the vibrator 31 and the vibrating plate 32 may be disposed in a stack manner. In this case, the vibrating plate 32 is located between the vibrator 31 and the display module 10. The lower surface (namely, a surface that is of the vibrating plate 32 and that faces the middle frame 11) of the vibrating plate 32 is connected to an upper surface (namely, a surface that is of the vibrator 31 and that faces the display module 10) of the vibrator 31. In addition, the upper surface of the vibrating plate 32 is connected to the lower surface A2 of the display module 10. The vibrator 31 may be connected to the display module 10 by using the vibrating plate 32.

In this case, in a vibration process, the vibrator 31 may be superimposed with the vibration of the vibrating plate 32 and coupled to the display module 10, to increase the vibration amplitude of the display module 10, so as to increase the volume for implementing sound on display.

In some embodiments of this application, the vibrating plate 32 may include a layer of electrostrictive sheets or a plurality of electrostrictive sheets disposed in a stack manner. Each electrostrictive sheet includes an upper electrode layer and a lower electrode layer made of a metal material, and an electrostrictive dielectric layer, for example, a piezoelectric ceramic dielectric layer, located between the upper electrode layer and the lower electrode layer.

On this basis, after a voltage is applied to the upper electrode layer and the lower electrode layer, the electrostrictive dielectric layer may be elastically deformed under the action of electric fields generated at the upper electrode layer and the lower electrode layer. In this way, in a deformation process, the electrostrictive dielectric layer drives the display module 10 to vibrate in the direction perpendicular to the upper surface A1 (shown in FIG. 5a) of the display module 10. In this case, the deformation form of the electrostrictive dielectric layer may be controlled by controlling parameters such as the intensity and the direction of the electric field, to control the vibration frequency of the display module 10.

Alternatively, in some other embodiments, the vibrating plate 32 may include a magnetostrictive material layer. On this basis, a conductive coil may be disposed outside the magnetostrictive material layer. The magnetostrictive material layer may be elastically deformed under action of an applied magnetic field generated after the conductive coil is powered on. In this way, in a deformation process, the magnetostrictive material layer drives the display module to vibrate in a direction perpendicular to the lower surface A2 (shown in FIG. 5a) of the display module 10.

For ease of description, the following provides description by using an example in which the vibrating plate 32 includes at least one piezoelectric ceramic layer.

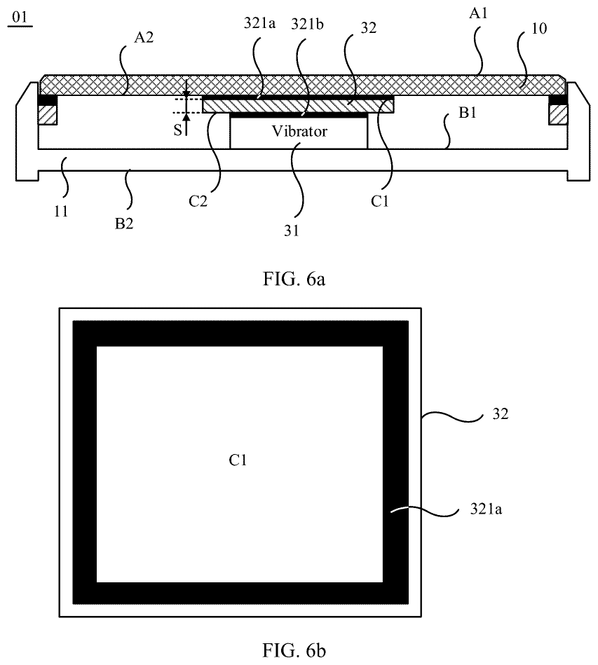

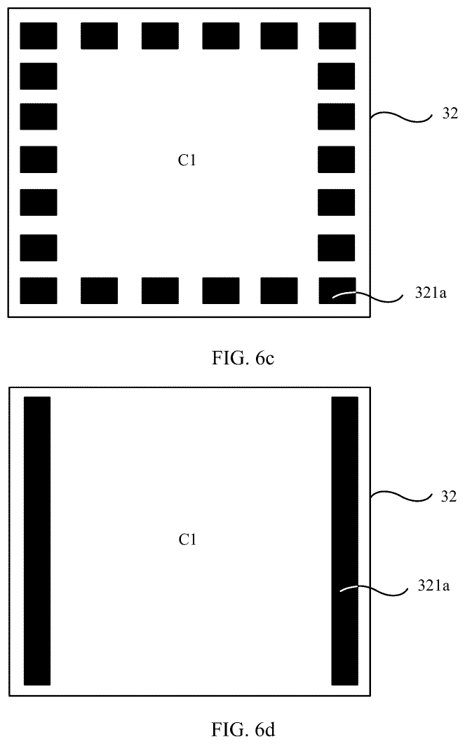

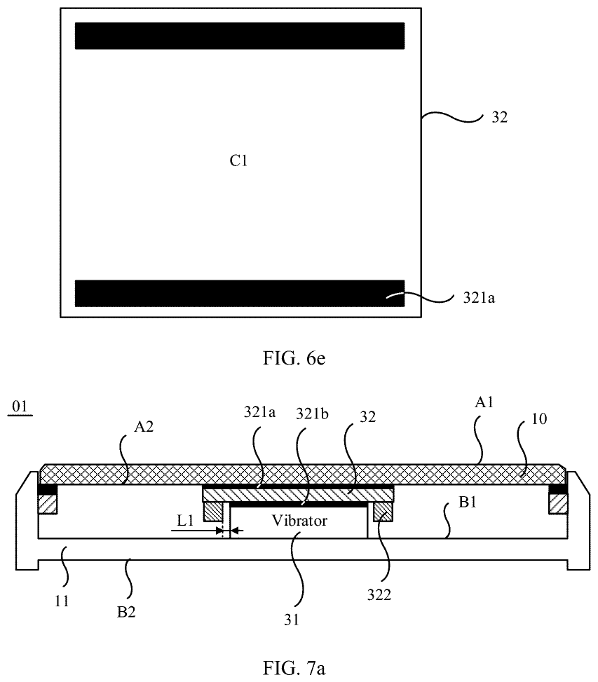

In a possible implementation of this example, as shown in FIG. 6a, the display terminal 01 includes a first glue layer 321a located on the upper surface C1 of the vibrating plate 32. The vibrating plate 32 is connected to the lower surface A2 of the display module 10 by using the first glue layer 321a.

For example, the first glue layer 321a may be an entire film layer with adhesive performance that covers the entire upper surface C1 of the vibrating plate 32.

Alternatively, the first glue layer 321a may have a specific glue layer pattern. For example, as shown in FIG. 6b, the glue layer pattern of the first glue layer 321a is disposed around an edge of the upper surface C1 of the vibrating plate 32. For example, the first glue layer 321a may be disposed around the edge of the upper surface C1 of the vibrating plate 32, to form a head-to-tail connected film layer of a frame structure.

Alternatively, for another example, as shown in FIG. 6c, the glue layer pattern of the first glue layer 321a is a plurality of block-shaped film layers disposed around the edge of the upper surface C1 of the vibrating plate 32.

Alternatively, for another example, as shown in FIG. 6d, the glue layer pattern of the first glue layer 321a includes two strip-like film layers disposed on a left side (close to the frame 113 on a left side of the middle frame 11) and a right side (close to the frame 113 on a right side of the display terminal 01) of the upper surface C1 of the vibrating plate 32.

Alternatively, for another example, as shown in FIG. 6e, the glue layer pattern of the first glue layer 321a includes two strip-like film layers disposed on the upper side (close to the frame 113 on an upper side of the display terminal 01) and the lower side (close to the frame 113 on a lower side of the display terminal 01) of the upper surface C1 of the vibrating plate 32.

It should be noted that the manner of disposing a structure or the pattern of the first glue layer 321a is merely described above by using an example. A person skilled in the art may perform force analysis based on a deformation form and a deformation degree of the vibrating plate 32 in a process of driving the display module 10 to vibrate, to obtain a disposing manner that is more conducive to driving the display module 10 to vibrate.

Other manners of disposing the structure or the pattern of the first glue layer 321a are not described herein one by one, provided that it can be ensured that in a deformation process, the vibrating plate 32 drives the display module 10 to vibrate in the direction perpendicular to the upper surface A1 of the display module 10.

In some embodiments of this application, the first glue layer 321a may be glue with relatively high adhesive strength, for example, double-component glue. Alternatively, in some other embodiments of this application, to facilitate the removal of the vibrating plate 32 from the display module 10 during maintenance of the display module 10, the first glue layer 321a may be adhesive (namely, double-sided tape).

In addition, as shown in FIG. 6a, the lower surface C2 of the vibrating plate 32 is connected to the vibrator 31 by using a second glue layer 321b. The second glue layer 321b is used to transfer the vibration of the vibrator 31 to the vibrating plate 32 while connecting the vibrator 31 to the vibrating plate 32, and then transfer the vibration to the display module 10 by using the vibrating plate 32. In this case, the second glue layer 321b may be an entire film layer with adhesive performance that covers the entire surface of the vibrator 31 that faces the vibrating plate 32.

It should be noted that there is a low probability that the vibrator 31 and the vibrating plate 32 are maintained. Therefore, to improve the bonding reliability of the vibrator 31 and the vibrating plate 32, the second glue layer 321b may be glue with relatively high adhesive strength. In addition, as shown in FIG. 6a, the area of the upper surface C1 of the vibrating plate 32 is greater than the area of the upper surface (namely, a surface on which the vibrator 31 is in contact with the vibrating plate 32) of the vibrator 31. In this case, one part of the vibrating plate 32 is connected to the vibrator 31 by using the second glue layer 321b, and the other part extends out of the vibrator 31, and is located around the vibrator 31.

In this way, there is a relatively large contact area between the upper surface C1 of the vibrating plate 32 and the display module 10 because the vibrating plate 32 is of a plate-like structure. Therefore, by setting the upper surface C1 and the lower surface C2 of the vibrating plate 32 to be respectively in contact with the display module 10 and the vibrator 31, the effective contact area between the vibrator 31 and the display module 10 may be increased, so that driving force provided by the vibrator 31 for the display module 10 in a vibration process can be more evenly applied to the display module 10, to reduce the probability that the display module 10 is damaged in the vibration process.

In addition, by increasing the area of the upper surface C1 of the vibrating plate 32, the area of the deformation region of the display module 10 may be further increased, so that the driving force provided by the vibrator 31 for the display module 10 in the vibration process can be transferred to the display module 10 to a greater extent, to improve the efficiency of driving, by the vibrator 31, the display module 10 to vibrate, reduce power consumption, and improve the effect for implementing sound on display.

Hardness of the vibrating plate 32 is related to the thickness S of the vibrating plate 32. In some embodiments of this application, the thickness S of the vibrating plate 32 may range from 0.2 mm to 2 mm. When the thickness of the vibrating plate 32 is less than 0.2 mm, the vibrating plate 32 features excessively small thickness S and relatively low hardness. After the audio digital processor 300 (shown in FIG. 1) outputs a driving signal, the vibrating plate 32 provides relatively weak driving force for the display module 10. In addition, the vibrating plate 32 can withstand a relatively small voltage output by the audio digital processor 300. In this case, the vibrating plate 32 has a relatively poor driving capability.

Alternatively, when the thickness S of the vibrating plate 32 is 2 mm, the vibrating plate 32 features excessively large thickness S and relatively high hardness. This is unfavorable for the vibrating plate 32 to vibrate under action of a driving signal. In addition, the overall thickness of the display terminal 01 is affected due to the excessively large thickness S of the vibrating plate 32.

In conclusion, when the thickness S of the vibrating plate 32 ranges from 0.2 mm to 2 mm, it may be ensured that the vibrating plate 32 has a specific driving capability when the vibrating plate 32 is prone to vibrate, and the impact of the thickness S of the vibrating plate 32 on the overall thickness of the display terminal 01 may be alleviated. In some possible implementations of this application, the thickness S of the vibrating plate 32 may be 0.2 mm, 0.3 mm, 0.5 mm, 0.8 mm, 1 mm, 1.5 mm, 1.8 mm, or 2 mm.

In addition, the hardness of the vibrating plate 32 is also related to a Young's modulus of the vibrating plate 32. When the thickness S of the vibrating plate 32 is increased in the thickness range, to enable the vibrating plate 32 to be more prone to vibrate, the Young's modulus of the vibrating plate 32 may be reduced. Alternatively, when the thickness S of the vibrating plate 32 is reduced in the thickness range, to enable the vibrating plate 32 to provide sufficient driving force for the display module 10, the Young's modulus of the vibrating plate 32 may be increased.

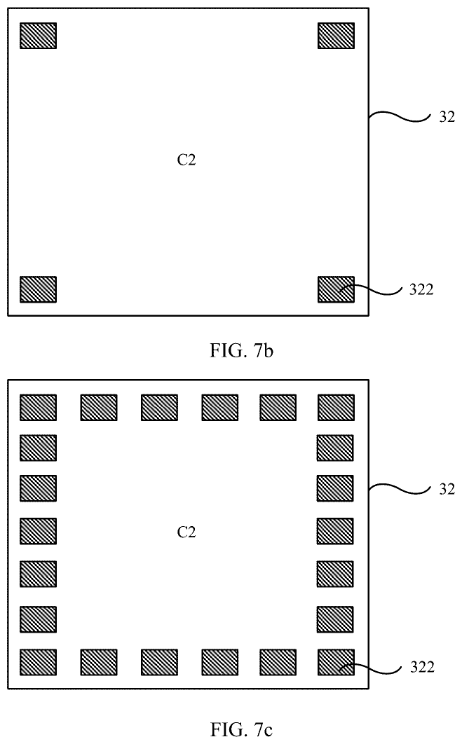

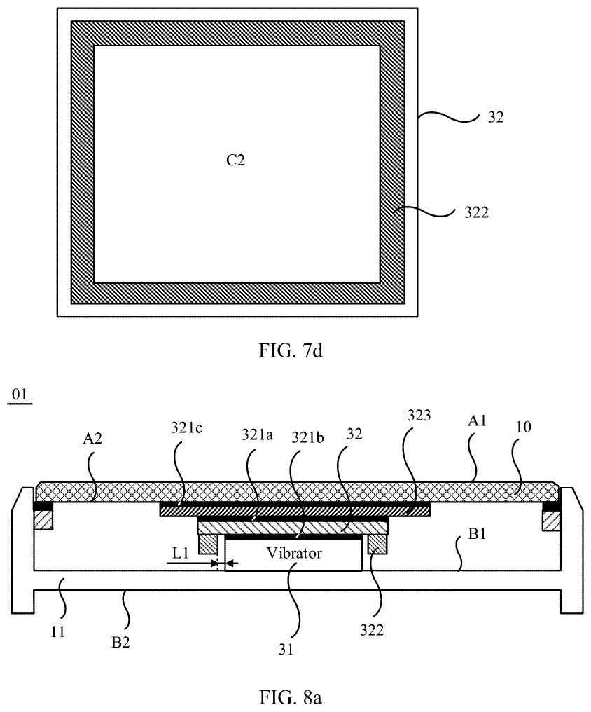

On this basis, to increase driving force coupled to the display module 10 by using the vibrating plate 32, in some embodiments of this application, the display module 10 further includes at least one first mass block 322 that is shown in FIG. 7a and located on the lower surface C2 (shown in FIG. 6a) of the vibrating plate 32.

The region in which the vibrator 31 is vertically projected on the lower surface C2 of the vibrating plate 32 and the region in which the first mass block 322 is vertically projected on the lower surface C2 of the vibrating plate 32 do not overlap. In this case, the first mass block 322 may be located around the vibrator 31, and there is a first gap L1 between the first mass block 322 and the vibrator 31.

A size of the first gap L1 is not limited in this application, provided that it can be ensured that a case in which vibration of the vibrator 31 is affected because in a vibration process of the vibrator 31, the first mass block 322 is in contact with the vibrator 31 is avoided. A manner of disposing the first mass block 322 on the lower surface C2 is described below by using an example in which the lower surface C2 of the vibrating plate 32 is a rectangle.

For example, as shown in FIG. 7b, the vibrating plate 32 may include four first mass blocks 322. Each first mass block 322 is located in one corner of the lower surface C2.

Alternatively, for another example, as shown in FIG. 7c, the vibrating plate 32 may include a plurality of (for example, at least four) first mass blocks 322. The plurality of first mass blocks 322 are disposed around an edge of the lower surface C2.

It should be noted that when the vibrating plate 32 includes a plurality of first mass blocks 322, in some embodiments of this application, parameters such as materials, thicknesses, and mass of first mass blocks 322 at different positions may be set based on the deformation form and the deformation degree of the vibrating plate 32.

For example, when the vibrating plate 32 vibrates, the first mass blocks 322 at different amplitude positions may differ in material, thickness, or mass, and the first mass blocks 322 at a same or similar amplitude position may have a same material, a same thickness, or same mass. A person skilled in the art may set the parameters of the plurality of first mass blocks 322 based on the deformation form and the deformation degree of the vibrating plate 32, and obtain, with reference to force analysis, a disposing manner that is more conducive to driving the display module 10 to vibrate.

Alternatively, as shown in FIG. 7d, the vibrating plate 32 may include one first mass block 322. The first mass block 322 is a head-to-tail connected frame structure disposed around the vibrator 31.

In some possible implementations of this application, the first mass block 322 may be made of a metal elemental material or a metal alloy material. In this case, as shown in FIG. 7a, the first mass block 322 is disposed at a part that is of the vibrating plate 32 and that extends out of the vibrator 31. Therefore, in a deformation process of the vibrating plate 32, the first mass block 322 may generate a vibration acceleration, and the acceleration is coupled to the display module 10 by using the vibrating plate 32, so that the driving force coupled to the display module 10 by using the vibrating plate 32 can be increased, to increase the volume for implementing sound on display.

It should be noted that the manner of disposing the first mass block 322 on the lower surface C2 is merely described above by using an example. A person skilled in the art may perform force analysis based on assistance of the first mass block 322 and the deformation form and the deformation degree of the vibrating plate 32 in the process of driving the display module to vibrate, to obtain a disposing manner that is more conducive to driving the display module to vibrate.

Other manners of disposing the first mass block 322 on the lower surface C2 are not described herein one by one, provided that it can be ensured that in the deformation process, the vibrating plate 32 can drive the display module 10 to vibrate in the direction perpendicular to the upper surface A1 of the display module 10.

### Example 2

In this example, a first mass block 322 is disposed on the lower surface C2 of the vibrating plate 32, which is the same as that in the example 1. The vibrating plate 32 is located between the vibrator 31 and the display module 10, and the lower surface of the vibrating plate 32 is connected to the upper surface of the vibrator 31. In addition, the upper surface of the vibrating plate 32 is connected to the lower surface A2 of the display module 10. The manner of disposing the first mass block 322 is the same as that described above. Details are not described herein.

The difference between this example and the example 1 lies in that the display module 10 further includes a first support sheet 323. The first support sheet 323 is located between the vibrating plate 32 and the display module 10.

The lower surface (namely, a surface that is of the first support sheet 323 and that faces the middle frame 11) of the first support sheet is connected to the upper surface of the vibrating plate 32. For example, the lower surface of the first support sheet 323 is connected to the upper surface C1 of the vibrating plate 32 by using a first glue layer 321a. The manner of disposing the first glue layer 321a is the same as that described above. Details are not described herein.

In addition, the upper surface (namely, a surface that is of the first support sheet 323 and that faces the display module 10) of the first support sheet 323 is connected to the lower surface A2 of the display module 10. For example, the first support sheet 323 may be connected to the lower surface A2 of the display module 10 by using a third glue layer 321c. The manner of disposing the third glue layer 321c may be the same as the manner of disposing the first glue layer 321a. Details are not described herein.

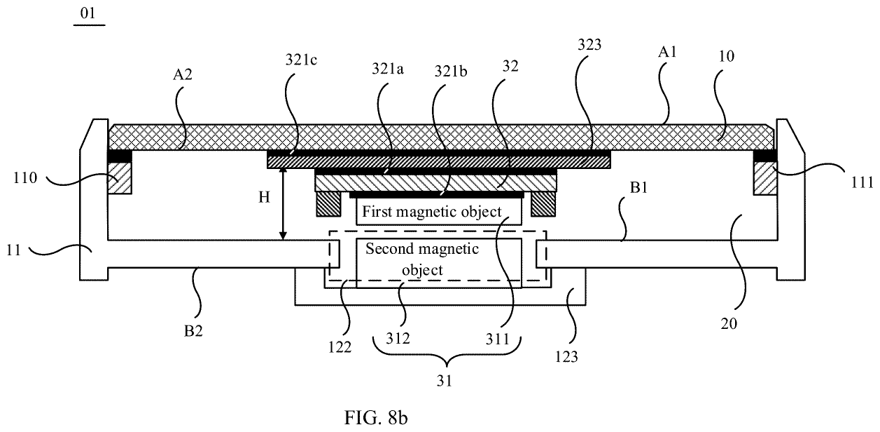

In addition, as shown in FIG. 8a, the area of the upper surface (namely, a surface on which the first support sheet 323 is in contact with the display module 10) of the first support sheet 323 is greater than the area of the upper surface of the vibrating plate 32.

In this way, there is a relatively large contact area between the first support sheet 323 and the display module 10 because the first support sheet 323 is of a sheet-like structure. Therefore, by setting the upper surface and the lower surface of the first support sheet 323 to be respectively in contact with the display module 10 and the vibrating plate 32, the effective contact area between the vibrating plate 32 and the display module 10 may be increased, so that the driving force provided by the vibrating plate 32 and the vibrator 31 for the display module 10 in a vibration process can be more evenly applied to the display module 10, to reduce the probability that the display module 10 is damaged in the vibration process.

In addition, by using the first support sheet 323, the area of the deformation region of the display module 10 may be further increased, so that the driving force provided by the vibrating plate 32 and the vibrator 31 for the display module 10 in the vibration process can be transferred to the display module 10 to a greater extent, to improve the efficiency of driving, by the vibrating plate 32 and the vibrator 31, the display module 10 to vibrate, reduce power consumption, and improve the effect for implementing sound on display.

It may be learned from the foregoing description that for the solutions in the example 1 and the example 2, the vibrating plate 32 is located between the vibrator 31 and the display module 10, and is connected to the vibrator 31 and the display module 10. In this case, a vibration structure that includes the vibrating plate 32 and the vibrator 31 may be disposed at a central position of the accommodation space 20 (shown in FIG. 4a), in other words, the vibration structure that includes the vibrating plate 32 and the vibrator 31 is connected to a central position of the display module 10.

In this way, under joint driving of the vibrator 31 and the vibrating plate 32, driving force may directly act on the central position of the display module 10 that serves as the diaphragm, to increase the amplitude of the entire display module 10. Therefore, in a process of implementing sound on display by using the display module 10 that serves as a speaker, both a low-frequency sound signal and a high-frequency sound signal can be transmitted at relatively high volume.

It may be learned from the foregoing description that in comparison with the example 1, in this example, the first support sheet 323 is further disposed between the vibrating plate 32 and the display module 10. In this case, in some embodiments of this example, to reduce the gap H between the display module 10 and the middle frame 11, a sum of a thickness of the vibrating plate 32 and a thickness of the first support sheet 323 may range from 0.2 mm to 2 mm. In addition, to increase the driving force from the vibrating plate 32, a Young's modulus of the vibrating plate 32 may be the same as a Young's modulus of the first support sheet 323.

In some other embodiments of this example, the vibrator 31 may include a first magnetic object 311 and a second magnetic object 312 that can move relatively and that are shown in FIG. 8b. In this case, to reduce the gap H between the display module 10 and the middle frame 11, a mounting hole 122 may be disposed on the middle frame 11. The second magnetic object 312 may pass through the mounting hole 122, and be fastened to a second surface B2 of the middle frame by using a bracket 123. A part of the second magnetic object 312 may be located in the mounting hole 122, and therefore the space occupied by the vibrator 31 in the accommodation space 20 may be reduced, to reduce the gap H between the display module and the middle frame 11, so as to reduce the thickness of the display terminal 01.

### Example 3

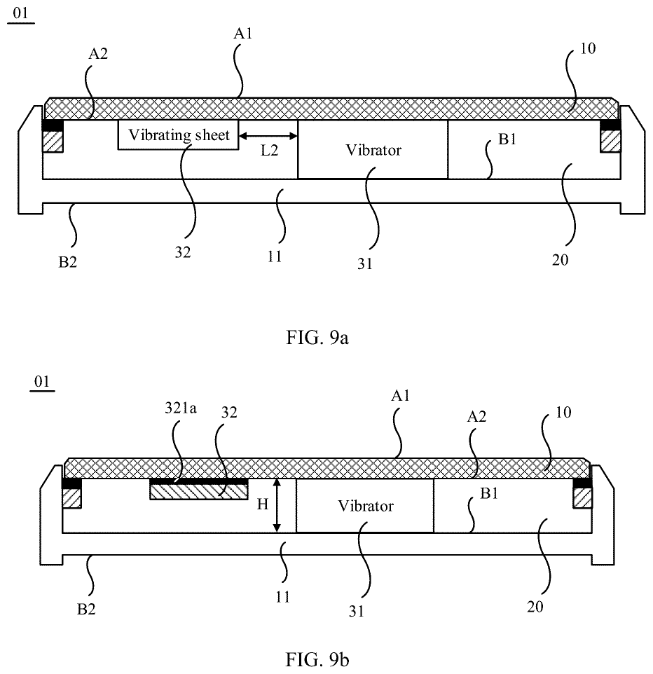

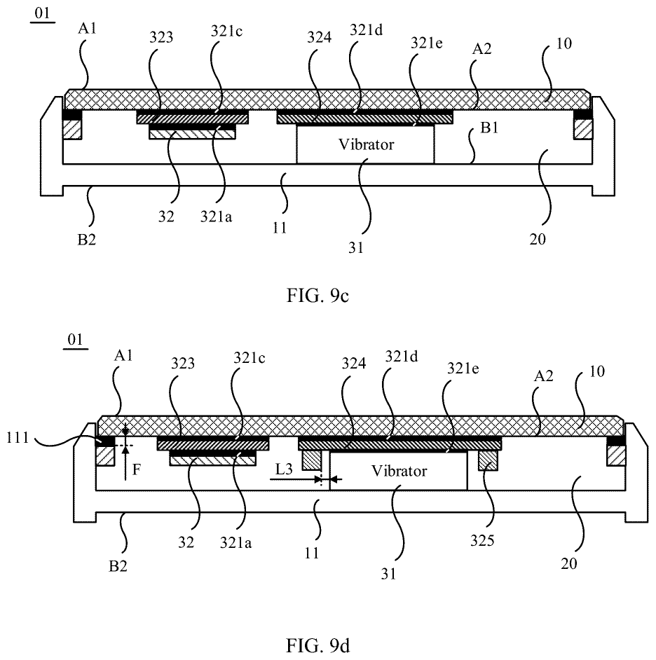

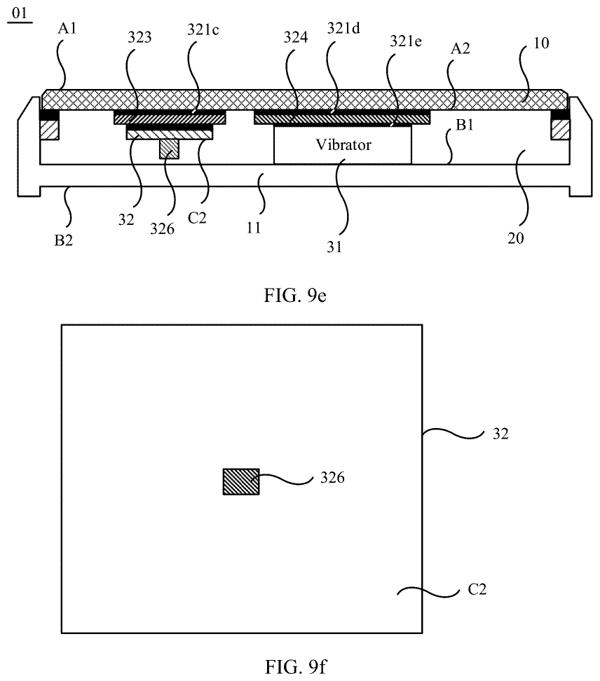

The difference between this example and the example 1 and the example 2 is shown in FIG. 9a, the upper surface of the vibrator 31 is connected to the lower surface A2 of the display module 10, and the lower surface of the vibrator 31 is connected to the middle frame 11. In addition, the region in which the vibrator 31 is vertically projected on the lower surface A2 of the display module 10 and the region in which the vibrating plate 32 is vertically projected on the lower surface A2 of the display module 10 do not overlap.

In this case, the vibrating plate 32 may be located around the vibrator 31. In addition, there is a second gap L2 between the vibrating plate 32 and the vibrator 31. The size of the second gap L2 is not limited in the embodiments of this application, provided that it can be ensured that in a vibration process of the vibrating plate 32 and the vibrator 31, no interference is caused due to the vibration of the vibrating plate 32 and the vibrator 31.

The material of which the vibrating plate 32 is made is the same as that described above. Details are not described herein. In this example, the vibrating plate 32 is disposed around the vibrator 31, which is different from the solution in which the vibrating plate 32 and the vibrator 31 are stacked in the example 1 and the example 2, to reduce the gap H between the display module 10 and the middle frame 11, so as to reduce the thickness of the display terminal 01.

In a possible implementation solution of this example, as shown in FIG. 9b, the vibrating plate 32 is connected to the lower surface A2 of the display module 10 by using a first glue layer 321a. The manner of disposing a film layer pattern of the first glue layer 321a and a material of which the first glue layer 321a is made are the same as those described above. Details are not described herein.

Alternatively, in another possible implementation solution of this example, the display module 10 further includes a first support sheet 323 shown in FIG. 9c. The first support sheet 323 is located between the vibrating plate 32 and the display module 10. The first support sheet 323 is connected to the upper surface C1 of the vibrating plate 32 by using the first glue layer 321a. In addition, the first support sheet 323 is connected to the lower surface A2 of the display module 10 by using a third glue layer 321c.

In addition, as shown in FIG. 9c, the display terminal 01 further includes a second support sheet 324. The second support sheet 324 is located between the vibrator 31 and the display module 10. The second support sheet 324 is connected to the lower surface A2 of the display module 10 by using a fourth glue layer 321d. In addition, the second support sheet 324 is further connected to the upper surface of the vibrator 31 by using a fifth glue layer 321e.

It should be noted that materials of the fourth glue layer 321d and the fifth glue layer 321e are the same as those described above. Details are not described herein. The vibration of the vibrator 31 may be coupled to the display module 10 by using the fourth glue layer 321d and the fifth glue layer 321e. The fourth glue layer 321d and the fifth glue layer 321e may be entire film layers respectively located on the second support sheet 324 and the upper surface of the vibrator 31.

In addition, the area of the upper surface (namely, a surface on which the second support sheet 324 is in contact with the display module 10) of the second support sheet 324 is greater than the area of the upper surface of the vibrator 31. In this case, one part of the second support sheet 324 is connected to the vibrator 31 by using the fifth glue layer 321e, and the other part extends out of the vibrator 31, and is located around the vibrator 31.

In this way, there is a relatively large contact area between the second support sheet 324 and the display module 10 because the second support sheet 324 is of a sheet-like structure. Therefore, by setting the upper surface and a lower surface of the second support sheet 324 to be respectively in contact with the display module 10 and the vibrator 31, the effective contact area between the vibrator 31 and the display module 10 may be increased, so that the driving force provided by the vibrator 31 for the display module 10 in a vibration process can be more evenly applied to the display module 10, to reduce the probability that the display module 10 is damaged in the vibration process.

In addition, by using the second support sheet 324, the area of the deformation region of the display module 10 may be further increased, so that the driving force provided by the vibrator 31 for the display module 10 in the vibration process can be transferred to the display module 10 to a greater extent, to improve the efficiency of driving, by the vibrator 31, the display module 10 to vibrate, reduce power consumption, and improve the effect for implementing sound on display.

It should be noted that the first support sheet 323 and the second support sheet 324 may be metal sheets. Materials of which the first support sheet 323 and the second support sheet 324 are made may be metal elemental materials or metal alloy materials.

On this basis, as shown in FIG. 9d, the display terminal 01 further includes at least one second mass block 325 disposed on the lower surface of the second support sheet 324. The region in which the vibrator 31 is vertically projected on the lower surface of the second support sheet 324 and the region in which the second mass block 325 is vertically projected on the lower surface of the second support sheet 324 do not overlap. In this case, the second mass block 325 is located around the vibrator 31, and there is a third gap L3 between the second mass block 325 and the vibrator 31.

It should be noted that the size of the third gap L3 is not limited in this application, provided that it can be ensured that a case in which vibration of the vibrator 31 is affected because in a vibration process of the vibrator 31, the second mass block 325 is in contact with the vibrator 31 is avoided.

In addition, the manner of disposing the at least one second mass block 325 on the lower surface of the second support sheet 324 and technical effects are the same as the manner of disposing the first mass block 322. Details are not described herein. A person skilled in the art may perform force analysis in a process of transferring the driving force from the vibrator 31 to the display module 10 by using the second support sheet 324, to obtain a disposing manner that is more favorable to drive the display module 10 to vibrate.

In this case, the second mass block 325 is disposed at a part that is of the second support sheet 324 and that extends out of the vibrator 31. Therefore, in the process of transferring the driving force from the vibrator 31 to the display module 10 by using the second support sheet 324, the second mass block 325 may generate a vibration acceleration, and the acceleration is coupled to the display module 10 by using the second support sheet 324, so that the driving force coupled to the display module 10 by using the second support sheet 324 can be increased, to increase the volume for implementing sound on display.

The second mass block 325 may be made of a metal material.

In addition, to increase the driving force coupled to the display module 10 by using the vibrating plate 32, in some embodiments of this application, the display terminal 01 further includes at least one third mass block 326 that is shown in FIG. 9e and located on the lower surface C2 of the vibrating plate 32.

A manner of disposing the third mass block 326 is the same as the manner of disposing the first mass block 322. The vibrating plate 32 may include four third mass blocks 326. Each third mass block 326 is located in one corner of the lower surface C2. Alternatively, for another example, the vibrating plate 32 may include a plurality of (for example, at least four) third mass blocks 326. The plurality of third mass blocks 326 are disposed around an edge of the lower surface C2. Alternatively, the vibrating plate 32 may include one third mass block 326. The third mass block 326 is a head-to-tail connected frame structure.

Alternatively, as shown in FIG. 9f, the vibrating plate 32 may include one third mass block 326. The third mass block 326 is located at a central position of the lower surface C2 of the vibrating plate 32.

In some possible implementations of this application, the third mass block 326 may be made of a metal elemental material or a metal alloy material. In this case, as shown in FIG. 9e, the third mass block 326 is disposed on the lower surface C of the vibrating plate 32. Therefore, in a deformation process of the vibrating plate 32, the third mass block 326 may generate a vibration acceleration, and the acceleration is coupled to the display module 10 by using the vibrating plate 32, so that the driving force coupled to the display module 10 by using the vibrating plate 32 can be increased, to increase the volume for implementing sound on display.

It should be noted that the manner of disposing the third mass block 326 on the lower surface C2 is merely described above by using an example. A person skilled in the art may perform force analysis based on the assistance of the third mass block 326 and the deformation form and the deformation degree of the vibrating plate 32 in a process of driving the display module 10 to vibrate, to obtain a disposing manner that is more conducive to driving the display module 10 to vibrate.

Other manners of disposing the third mass block 326 on the lower surface C2 are not described herein one by one, provided that it can be ensured that in the deformation process, the vibrating plate 32 can drive the display module 10 to vibrate in the direction perpendicular to the lower surface A2 of the display module 10.

It may be learned from the foregoing description that for the solution in the example 3, as shown in FIG. 9a, the vibrating plate 32 is located around the vibrator 31. The vibrator 31 (or the vibrating plate 32) may be disposed at a central position of the accommodation space 20 (shown in FIG. 4a), to be connected to a central position of the display module 10. The vibrating plate 32 (or the vibrator 31) is disposed at an edge position of the accommodation space 20, and the part may serve as a receiver of a mobile phone.

In this way, driving force provided when the vibrator 31 (or the vibrating plate 32) connected to the central position of the display module 10 vibrates may directly act on the central position of the display module 10 that serves as the diaphragm, to increase the amplitude of the entire display module 10. Therefore, in a process of implementing sound on display by using the display module 10 that serves as a speaker, both a low-frequency sound signal and a high-frequency sound signal can be transmitted at relatively high volume.

In addition, when the vibrating plate 32 (or the vibrator 31) close to the edge position of the accommodation space 20 vibrates, the amplitude of the display module 10 at the edge position may be increased. Therefore, in a process of implementing sound on display by using the display module 10 that serves as a receiver, a high-frequency sound signal can be transmitted at relatively high volume.

In any one of the foregoing examples, it may be learned from the foregoing description that an adhesive layer 111 shown in FIG. 9d is disposed between the display module and the middle frame 11. In a possible implementation of this application, the thickness F of the adhesive layer 111 may range from 0.2 mm to 0.5 mm, and a Young's modulus of the adhesive layer 111 may range from 10 Mpa to 80 Mpa.

When the thickness F of the adhesive layer 111 is less than 0.2 mm, the adhesive layer 111 has excessively low adhesive strength. This is unfavorable to firmly bond the display module 10 and the middle frame 11.

When the thickness F of the adhesive layer 111 ranges from 0.2 mm to 0.5 mm, the adhesive layer 111 can firmly bond the display module 10 and the middle frame 11. In addition, in the thickness range, a larger thickness F of the adhesive layer 111 indicates a softer texture of the adhesive layer 111 and a higher probability that the display module 10 vibrates after force is applied. This is conducive to increasing the volume for implementing sound on display.

For example, the thickness F of the adhesive layer 111 may be 0.2 mm, 0.3 mm, 0.4 mm, or 0.5 mm.

When the thickness F of the adhesive layer 111 is greater than 0.5 mm, the adhesive layer 111 has an excessively soft texture. Therefore, in a vibration process of the display module the boundary condition of the display terminal 01 is softer, and the reliability of the entire display terminal 01 is reduced, and consequently the display 101 is prone to a risk of being broken.

In addition, when the Young's modulus of the adhesive layer 111 may range from 10 Mpa to 80 Mpa, a smaller Young's modulus of the adhesive layer 111 indicates a softer boundary condition of the display terminal 01 and a higher probability that the display module 10 vibrates. In this way, the volume for implementing sound on display can be effectively increased.

It may be learned from the foregoing description that in the display terminal 01, after receiving the driving signal output by the audio digital processor 300, each of the vibrator 31 and the vibrating plate 32 may drive, in the direction perpendicular to the lower surface A2 of the display module 10, the display module 10 to vibrate, to implement sound on display. An implementation of how the vibrator 31 and the vibrating plate 32 receive the driving signal output by the audio digital processor 300 is described below by using an example.

### Example 4

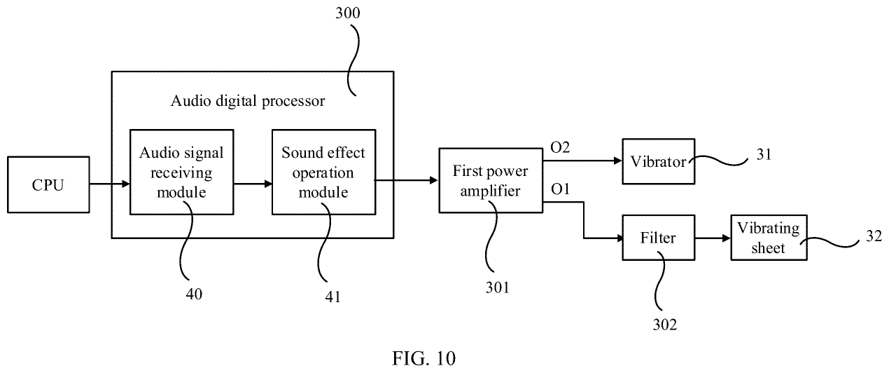

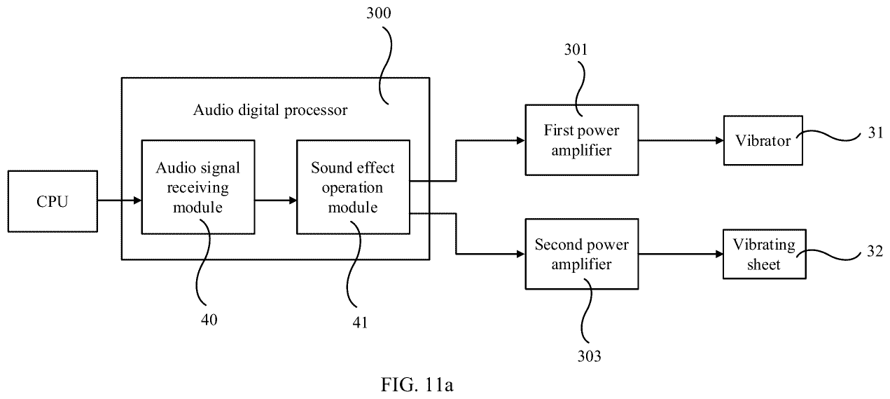

In this example, the display terminal 01 includes an audio digital processor 300, a first power amplifier 301, and a filter 302 shown in FIG. 10.

An output end of the audio digital processor 300 is coupled to the input end of the first power amplifier 301. The audio digital processor 300 is configured to output an audio signal to the first power amplifier 301.

In some embodiments of this application, the audio digital processor 300 includes an audio signal receiving module 40 and a sound effect operation module 41. The audio signal receiving module 40 may be electrically connected to the CPU that is disposed on the PCB and shown in FIG. 1, to receive an audio signal output by the CPU.

In addition, the sound effect operation module 41 is configured to adjust a frequency band of the audio signal output by the audio signal receiving module 40, to adjust an audio effect.

For example, when a low frequency of the audio signal output by the audio signal receiving module 40 is insufficient, the sound effect operation module 41 may increase the frequency of a low-frequency part output by the audio signal receiving module 40. Alternatively, when a high frequency of the audio signal output by the audio signal receiving module 40 is relatively high, the sound effect operation module 41 may reduce the frequency of a high-frequency part output by the audio signal receiving module 40. Therefore, audio output by the audio digital processor 300 can meet a requirement of an audio signal to be processed by the first power amplifier 301.

It should be noted that the audio signal output by the CPU may be an audio signal generated when the display terminal 01 plays a sound, for example, music or a video. Alternatively, the audio signal may be a sound transmitted to the CPU by using a receiver when the display terminal 01 is on a voice call. The frequency of an audio signal that can be received by a human ear usually ranges from 200 Hz to 20 kHz. Therefore, the frequency of the audio signal output by the CPU may range from 200 Hz to 20 kHz.

On this basis, a first output end 01 of the first power amplifier 301 is coupled to the filter 302. A second output end 02 of the first power amplifier 301 is coupled to the vibrator 31. The first power amplifier 301 is configured to perform power amplification processing on the audio signal processed by the sound effect operation module 41, so that the vibrator 31 can be driven to vibrate after receiving the audio signal (at hundreds of kHz, for example, 400 kHz) output by the first power amplifier 301, and a vibration phase of the vibrator 31 is a first phase. In some embodiments of this application, the first power amplifier 301 may be a smart (smart) power amplifier (power amplifier, PA) that is of a class H type and that is with a relatively high output frequency.

It may be learned from the foregoing description that when the vibrator 31 includes the first magnetic object 311 and the second magnetic object 312, the first magnetic object 311 or the second magnetic object 312 may be a coil. In this case, after the vibrator 31 receives the audio signal that is at 400 kHz and output by the first power amplifier 301, the coil may serve an inductor, filter out a part of the audio, and drive, under action of the filtered audio signal, the display module 10 to emit a sound at a frequency that ranges from 200 Hz to 20 kHz.

In addition, it may be learned from the foregoing description that the vibrating plate 32 mainly includes the vibrating plate 32, and the vibrating plate 32 may be equivalent to a capacitor. Therefore, when the first power amplifier 301 that can output an audio signal at hundreds of kHz is directly coupled to the vibrating plate 32, the vibrating plate 32 is short-circuited. Therefore, the filter 302 needs to be coupled between the first power amplifier 301 and the vibrating plate 32.

The filter 302 is configured to filter the audio signal processed by the sound effect operation module 41. For example, a part of the audio signal that is at 400 kHz and output by the first power amplifier 301 is filtered out, so that the vibrating plate 32 vibrates in the first phase under control of the filtered audio signal, and drives the display module 10 to emit a sound at a frequency that ranges from 200 Hz to 20 kHz.

For ease of description, in the range from 200 Hz to 20 kHz, an audio signal at 200 Hz to 4 kHz may be referred to as a low-frequency signal, and a signal at 4 kHz to 20 kHz may be referred to as an intermediate-frequency signal or a high-frequency signal. In this application, division into the low-frequency signal, the intermediate-frequency signal, and the high-frequency signal is merely an example for description, and is not intended to limit the low-frequency signal, the intermediate-frequency signal, and the high-frequency signal.

On this basis, a process in which the vibrator 31 and the vibrating plate 32 drive, based on the frequency of the audio signal output by the CPU, the display module 10 to implement sound on display is described below.

For example, when the CPU in FIG. 10 outputs a low-frequency signal at 1 kHz, after the low-frequency signal passes through the audio digital processor 300 and the first power amplifier 301, an audio signal that is at hundreds of kHz and output by the first power amplifier 301 is applied to the vibrator 31, to drive the vibrator 31 to vibrate. The vibrator 31 that serves as an inductor filters out a part of the audio signal at hundreds of kHz, and vibrates under action of the remaining audio signal at 1 kHz.

In addition, after the audio signal that is at hundreds of kHz and output by the first power amplifier 301 passes through the filter 302, a part of the audio signal at hundreds of kHz is filtered out, and the remaining audio signal at 1 kHz is applied to the vibrating plate 32.

The vibrator 31 and the vibrating plate 32 are connected in parallel, and therefore a same voltage is applied to the vibrator 31 and the vibrating plate 32. On this basis, under the driving of the low-frequency signal at 1 kHz, there is relatively small impedance (for example, 8 ohms) for a coil in the vibrator 31, and therefore a relatively strong current flows through the coil. There is relatively large impedance (for example, 200 ohms) for the vibrating plate 32 that serves as a capacitor, and therefore a relatively weak current flows through the vibrating plate 32. In this case, when the vibrator 31 and the vibrating plate 32 simultaneously vibrate, the vibration of the vibrator 31 and the vibrating plate 32 may be superimposed because the vibration phases are the same, and the vibrator 31 serves as the main driving source to drive the display module 10 to vibrate, to emit a low-frequency signal at 1 kHz.

Alternatively, when the CPU in FIG. 10 outputs a high-frequency signal at 10 kHz, after the high-frequency signal passes through the audio digital processor 300 and the first power amplifier 301, an audio signal that is at hundreds of kHz and output by the first power amplifier 301 is applied to the vibrator 31, to drive the vibrator 31 to vibrate. The vibrator 31 that serves as an inductor filters out a part of the audio signal at hundreds of kHz, and vibrates under the action of the remaining audio signal at 10 kHz.

In addition, after the audio signal that is at hundreds of kHz and output by the first power amplifier 301 passes through the filter 302, a part of the audio signal at hundreds of kHz is filtered out, and the remaining audio signal at 10 kHz is applied to the vibrating plate 32.

The vibrator 31 and the vibrating plate 32 are connected in parallel, and therefore the same voltage is applied to the vibrator 31 and the vibrating plate 32. On this basis, under the driving of the high-frequency signal at 10 kHz, there is relatively large impedance (for example, ohms) for a coil in the vibrator 31, and therefore a relatively weak current flows through the coil. There is relatively small impedance (for example, 2 ohms) for the vibrating plate 32 that serves as a capacitor, and therefore a relatively strong current flows through the vibrating plate 32. In this case, when the vibrator 31 and the vibrating plate 32 simultaneously vibrate, the vibration of the vibrator 31 and the vibrating plate 32 may be superimposed, and the vibrating plate 32 may serve as a main driving source to drive the display module 10 to vibrate, to emit a high-frequency signal at 10 kHz, so as to solve the problem that a high-frequency signal is emitted on the display at relatively low volume.

### Example 5

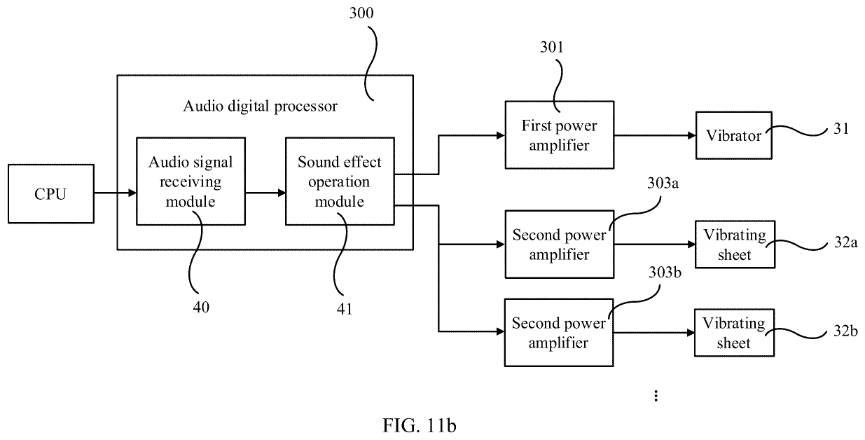

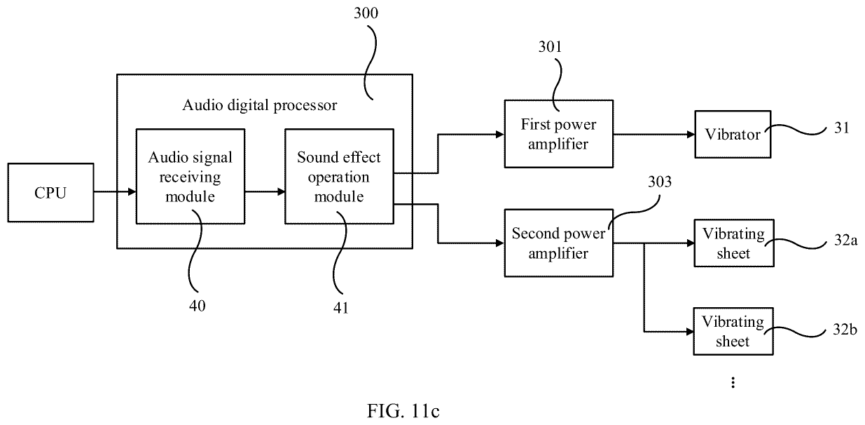

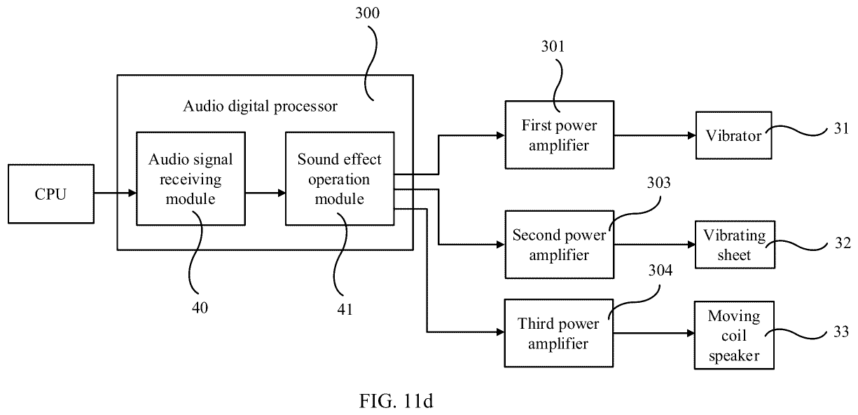

In this example, the display terminal 01 includes an audio digital processor 300, a first power amplifier 301, and a second power amplifier 303 shown in FIG. 11a. The output frequency of the first power amplifier 301 is greater than the output frequency of the second power amplifier 303.

For example, the first power amplifier 301 may be the foregoing smart PA of the class H type, and the second power amplifier 303 may be a smart PA of an AB type.

The output end of the audio digital processor 300 is coupled to the input end of the first power amplifier 301 and the second power amplifier 301. The audio digital processor 300 is configured to output an audio signal to the first power amplifier 301 and the second power amplifier 303.

A structure of the audio digital processor 300 is the same as that in the example 4. Details are not described herein.

In addition, the output end of the first power amplifier 301 is coupled to the vibrator 31. The first power amplifier 301 is configured to amplify the audio signal output by the audio digital processor 300, to drive the vibrator 31 to vibrate.

The output end of the second power amplifier 303 is coupled to the vibrating plate 32, and the second power amplifier 303 is configured to amplify the audio signal output by the audio digital processor 300, so that a vibration phase of the vibrating plate 32 is a first phase.

The second power amplifier 303 has a relatively low output frequency, and therefore when the vibrating plate 32 includes the vibrating plate 32, a signal output by the second power amplifier 303 can drive the vibrating plate 32 to vibrate, and the vibrating plate 32 can be prevented from being short-circuited.

In addition, it may be learned from the foregoing description that the display terminal 01 may include a plurality of vibrating plates, for example, a vibrating plate 32a and a vibrating plate 32b shown in FIG. 11b. On this basis, in some embodiments of this application, as shown in FIG. 11b, the display terminal 01 may include a plurality of second power amplifiers, for example, a second power amplifier 303a and a second power amplifier 303b. Each second power amplifier 303 is coupled to one vibrating plate 32.

In this way, each vibrating plate 32 may be independently controlled by using one second power amplifier 303. When relatively high volume is required for implementing sound on display, it may be set that each second power amplifier 303 drives a vibrating plate 32 coupled to the second power amplifier 303 to vibrate. In this case, all the vibrating plates 32 provide driving force for the display module 10, so that a vibration frequency of the display module 10 can be increased, to increase the volume for implementing sound on display. Alternatively, when relatively low volume is required for implementing sound on display, it may be set that some second power amplifiers 303 drive vibrating plates 32 coupled to the second power amplifiers 303 to vibrate. In this case, only some vibrating plates 32 provide driving force for the display module 10, and therefore there is no excessively high volume for implementing sound on display.

Alternatively, in some other embodiments of this application, as shown in FIG. 11c, the display terminal 01 may include one second power amplifier 303 and a plurality of vibrating plates, for example, a vibrating plate 32a and a vibrating plate 32b, coupled to the second power amplifier 303. In this way, the plurality of vibrating plates may be simultaneously controlled, by using the one second power amplifier 303, to vibrate. Therefore, a circuit structure of the display terminal 01 can be simplified.

It should be noted that letters “a” and “b” after an identifier “32” of the vibrating plate are merely used to distinguish between different vibrating plates, and the letters constitute no limitation on a structure of the vibrating plate. In addition, letters “a” and “b” after an identifier “303” of the second power amplifier are merely used to distinguish between different second power amplifiers, and the letters constitute no limitation on a structure of the second power amplifier.

In addition, when the display terminal 01 further includes a moving coil speaker 33 shown in FIG. 11d, the display terminal 01 may include a third power amplifier 304 coupled to the audio digital processor 300 and the moving coil speaker 33. The third power amplifier 304 may be the foregoing smart PA of the class H type.

In this way, after the audio digital processor 300 outputs the audio signal, under respective control of the first power amplifier 301 and the second power amplifier 303, the vibrator 31 and the vibrating plate 32 jointly drive the display module 10 to vibrate, to implement sound on display. The third power amplifier 304 controls the moving coil speaker to emit a sound signal, so that the display terminal 01 can implement multi-channel sound.

The foregoing descriptions are merely specific implementations of this application, but are not intended to limit the protection scope of this application. Any variation or replacement within the technical scope disclosed in this application shall fall within the protection scope of this application. Therefore, the protection scope of this application shall be subject to the protection scope of the claims.

1. A display terminal, comprising:
a middle frame;
a display module, connected to the middle frame, wherein an accommodation space is formed between the display module and the middle frame;
a vibrator, wherein at least a part of the vibrator is disposed in the accommodation space, and the vibrator is connected to the display module or the middle frame; and
at least one vibrating plate, located in the accommodation space, wherein an upper surface of the vibrating plate is connected to a lower surface of the display module, and a lower surface of the vibrating plate faces the middle frame; and
wherein in a direction perpendicular to the upper surface of the vibrating plate, the vibrator and the vibrating plate are configured to drive the display module to vibrate.

2. The display terminal according to claim 1, wherein the display terminal further comprises a first support sheet;
the first support sheet is located between the vibrating plate and the display module, an upper surface of the first support sheet is connected to the lower surface of the display module, and a lower surface of the first support sheet is connected to the upper surface of the vibrating plate; and
an area of the upper surface of the first support sheet is greater than an area of the upper surface of the vibrating plate.

3. The display terminal according to claim 1, wherein
the vibrating plate is located between the vibrator and the display module, the lower surface of the vibrating plate is connected to an upper surface of the vibrator, and a lower surface of the vibrator is connected to the middle frame.

4. The display terminal according to claim 3, wherein the area of the upper surface of the vibrating plate is greater than an area of the upper surface of the vibrator.

5. The display terminal according to claim 4, wherein the display terminal further comprises at least one first mass block, and the first mass block is disposed on the lower surface of the vibrating plate; and
a region in which the vibrator is vertically projected on the lower surface of the vibrating plate and a region in which the first mass block is vertically projected on the lower surface of the vibrating plate do not overlap.

6. The display terminal according to claim 1, wherein
an upper surface of the vibrator is connected to the lower surface of the display module, and a lower surface of the vibrator is connected to the middle frame; and
a region in which the vibrator is vertically projected on the lower surface of the display module and a region in which the vibrating plate is vertically projected on the lower surface of the display module do not overlap.

7. The display terminal according to claim 6, wherein the display terminal further comprises a second support sheet;
the second support sheet is located between the vibrator and the display module, an upper surface of the second support sheet is connected to the lower surface of the display module, and a lower surface of the second support sheet is connected to the upper surface of the vibrator; and
an area of the upper surface of the second support sheet is greater than an area of the upper surface of the vibrator.

8. The display terminal according to claim 7, wherein the display terminal further comprises at least one second mass block, and the second mass block is disposed on the lower surface of the second support sheet; and
a region in which the vibrator is vertically projected on the lower surface of the second support sheet and a region in which the second mass block is vertically projected on the lower surface of the second support sheet do not overlap.

9. The display terminal according to claim 8, wherein the display terminal further comprises at least one third mass block, and the third mass block is disposed on the lower surface of the vibrating plate.

10. The display terminal according to claim 1, wherein the display terminal further comprises a first glue layer located on the upper surface of the vibrating plate; and
the first glue layer is disposed along an edge of the upper surface of the vibrating plate.

11. The display terminal according to claim 1, wherein a thickness of the vibrating plate ranges from 0.2 mm to 2 mm.

12. The display terminal according to claim 1, wherein an adhesive layer is disposed between the display module and the middle frame, a thickness of the adhesive layer ranges from 0.2 mm to 0.5 mm, and a Young's modulus of the adhesive layer ranges from 10 Mpa to 80 Mpa.

13. The display terminal according to claim 1, wherein the vibrator comprises a first magnetic object and a second magnetic object, the first magnetic object is connected to the display module, and the second magnetic object is connected to the middle frame.

14. The display terminal according to claim 1, wherein the display terminal comprises an audio digital processor, a first power amplifier, and a filter;
an output end of the audio digital processor is coupled to an input end of the first power amplifier, and the audio digital processor is configured to output an audio signal to the first power amplifier;
a first output end of the first power amplifier is coupled to the filter, a second output end of the first power amplifier is coupled to the vibrator, and the first power amplifier is configured to amplify the audio signal, and a vibration phase of the vibrator is a first phase; and
an output end of the filter is connected to the vibrating plate, and the filter is configured to filter the audio signal, so that a vibration phase of the vibrating plate is the first phase.

15. The display terminal according to claim 1, wherein the display terminal comprises an audio digital processor, a first power amplifier, and a second power amplifier, and an output frequency of the first power amplifier is greater than an output frequency of the second power amplifier;
an output end of the audio digital processor is coupled to an input end of the first power amplifier and the second power amplifier, and the audio digital processor is configured to output an audio signal to the first power amplifier and the second power amplifier;
an output end of the first power amplifier is coupled to the vibrator, and the first power amplifier is configured to amplify the audio signal, and a vibration phase of the vibrator is a first phase; and
an output end of the second power amplifier is coupled to the vibrating plate, and the second power amplifier is configured to amplify the audio signal, so that a vibration phase of the vibrating plate is the first phase.
